(19) United States
(12) Patent Application Publication
(10) Pub. No.: US 2013/0122632 A1
(43) Pub. Date: May 16, 2013

(54) METHOD OF MANUFACTURING SOLAR CELL MODULE

(71) Applicant: Sanyo Electric Co., Ltd., Moriguchi City (JP)

(72) Inventor: Yoshihide Kawashita, Nara City (JP)

(73) Assignee: SANYO ELECTRIC CO., LTD., Moriguchi City (JP)

(21) Appl. No.: 13/683,094

(22) Filed: Nov. 21, 2012

Related U.S. Application Data
(63) Continuation of application No. PCT/JP2011/062376, filed on May 30, 2011.

(30) Foreign Application Priority Data
May 31, 2010 (JP) 2010-124427

(51) Int. Cl. H01L 31/18

(52) U.S. Cl. CPC H01L 31/18
USPC 438/64

(57) ABSTRACT

A method of manufacturing a solar cell module includes a step of connecting electrodes of solar cells with an interconnection tab so as to form a first solar cell unit, by welding the interconnection tab to the electrodes while remaining an unmelted part of solder of the interconnection tab, and a step of connecting an interconnection tab of a second solar cell unit to the interconnection tab of the first solar cell unit at the unmelted part of the interconnection tab of the first solar cell unit.

### CROSS REFERENCE TO RELATED APPLICATIONS

This application is a continuation application of International Application No. PCT/JP2011/0062376, filed on May 30, 2011, entitled “METHOD OF MANUFACTURING SOLAR CELL MODULE”, which claims priority based on Article 8 of Patent Cooperation Treaty from prior Japanese Patent Applications No. 2010-124427, filed on May 31, 2010, the entire contents of which are incorporated herein by reference.

### BACKGROUND OF THE INVENTION

1. Field of the Invention

This disclosure relates to a method of manufacturing a solar cell module.

2. Description of Related Art

A solar cell system uses a solar cell module including several tens of solar cells as power sources arranged on a flat plane in order to protect the solar cells from external damage and to facilitate the handling of them.

Document 1 (Japanese Patent Application Publication No. 2007-235113) has recently proposed a solar cell module which enhances the charging rate of the solar cells and the efficiency of using an ingot of a material for the substrates of the solar cells.

The document 1 describes a solar cell module in which quadrilateral solar cells each of which having an oblique side are arranged on a flat plane such that oblique sides of each two of the solar cells face each other to form a substantially rectangular outline, and the solar cells whose oblique sides face each other are connected to each other in parallel with interconnection tabs.

In the solar cell module, the solar cells are connected to each other in parallel with the interconnection tabs using solder to form a solar cell unit, and solar cell units each having the solar cells connected in parallel are connected to each other in series using other interconnection tabs. Usually, the interconnection tabs are formed by dipping a copper foil in solder.

In the step of the interconnection tab connection, the solar cells are connected to each other with solder-coated interconnection tabs by welding the interconnection tabs to the solar cells, that is, by heating while pressing the interconnection tabs to the solar cells. The solar cell unit is formed by connecting the solar cells to each other with the interconnection tabs on the rear side. Then, in a step of forming a string, to the interconnection tabs connected to the rear surface of one of the solar cell units, interconnection tabs being connected or to be connected to a front surface of adjacent solar cell unit needs to be connected. When the solar cells are connected to each other in the previous step, the solder of the interconnection tabs on the rear surface of the solar cell unit is flattened. For this reason, there is a possibility that the interconnection tabs have only a small amount of solder therebetween in the latter connection step, which might lower the connection strength of the interconnection tabs.

Meanwhile, a solar cell module aiming to reduce optical loss caused by interconnection tabs has been proposed (by, for example, Document 2: Japanese Patent Application Publication No. 2006-13406). In such a solar cell, multiple indentations are formed in the front surface of each interconnection tab so that light incident on the interconnection tabs can be diffused by the indentations and reflected by a translucent protection material such as a glass and then enter the solar cells.

In such an interconnection tab having multiple indentations, solder is not provided to the surface having the indentations.

When the interconnection tabs having no solder on the front surfaces are used, the connect strength of the interconnection tabs might decrease, which requires additional work such as additional soldering.

### SUMMARY OF THE INVENTION

An embodiment of the invention aims to improve the connection strength of the interconnection tabs without needing additional work such as additional soldering.

One aspect of the invention is a method of manufacturing a solar cell module. The method includes: a first welding step of connecting rear-side electrodes of solar cells with a rear-side interconnection tab to form a solar cell unit; and a second welding step of connecting a front-side interconnection tab of another solar cell unit adjacent to the solar cell unit to the rear-side interconnection tab of the solar cell unit, at an unwelded part of solder of the rear interconnection tab of the solar cell unit.

The first welding step may connect the rear-side interconnection tab to the rear-side electrodes while remaining the unwelded part at the area to which the front-side interconnection tab is to be connected in the second welding step.

The second welding step may connect, in a state where an end portion of the front-side interconnection tab of the another solar cell unit is placed on the unwelded part of the rear-side interconnection tab of the solar cell unit, the front-side interconnection tab of the another solar cell unit to the rear-side interconnection tab of the solar cell unit, by melting the unwelded part.

The front-side interconnection tab may comprise a solder layer on one side and no solder layer on the other side thereof.

The front-side interconnection tab may comprise no solder layer thereon.

The front-side interconnection tab may comprise indentations to diffuse light at least on a front surface thereof.

According to the aspect, the solder layer of the rear-side interconnection tab is kept unwelded at the area of the rear-side interconnection tab to be connected to the front-side interconnection tab. With this, upon the welding step in which the front-side interconnection tab being connected or to be connected to the front-side electrodes is connected to the rear-side interconnection tab, a portion between the rear-side interconnection tab and the front-side interconnection tab still has the unwelded solder layer of the rear-side interconnection tab. Therefore, the interconnection tabs can have a sufficient amount of solder therebetween, allowing improvement in connection strength and in reliability.

### BRIEF DESCRIPTION OF THE DRAWINGS

FIG. 1 is a plan view showing the configuration of a solar cell substrate which has not been divided into four solar cells yet.

FIG. 2 is a plan view of two of the divided four solar cells seen from the front side.

FIG. 3 is a plane view of the two solar cells seen from the rear side.

FIG. 4 is a plan view of a solar cell unit according to an embodiment of the invention, seen from the rear side.

FIG. 5 is a plan view of the solar cell unit according to the embodiment of the invention, seen from the front side.

FIG. 6 is a plan view of solar cell units according to the embodiment of the invention, seen from the front side.

FIG. 7 is a plan view of solar cell units according to the embodiment of the invention, seen from the rear side.

FIG. 8A is a schematic sectional view showing a connection state of the solar cell units, before welding, according to the embodiment of the invention.

FIG. 8B is a schematic sectional view showing a connection state of the solar cell units, after welding, according to the embodiment of the invention.

FIG. 9 is a schematic sectional view showing how the solar cell units according to the embodiment of the invention are connected to each other.

FIG. 10A is a schematic sectional view showing a connection state of solar cell units, before welding, according to a modification.

FIG. 10B is a schematic sectional view showing a connection state of the solar cell units, after welding, according to the modification.

FIG. 11 is a schematic sectional view of a solar cell module according to the embodiment of the invention.

### DETAILED DESCRIPTION OF EMBODIMENTS

An embodiment of the invention is described in detail with reference to the drawings. Note that the same or corresponding parts are given the same reference numerals throughout the drawings, and are not described again to avoid repetitive descriptions.

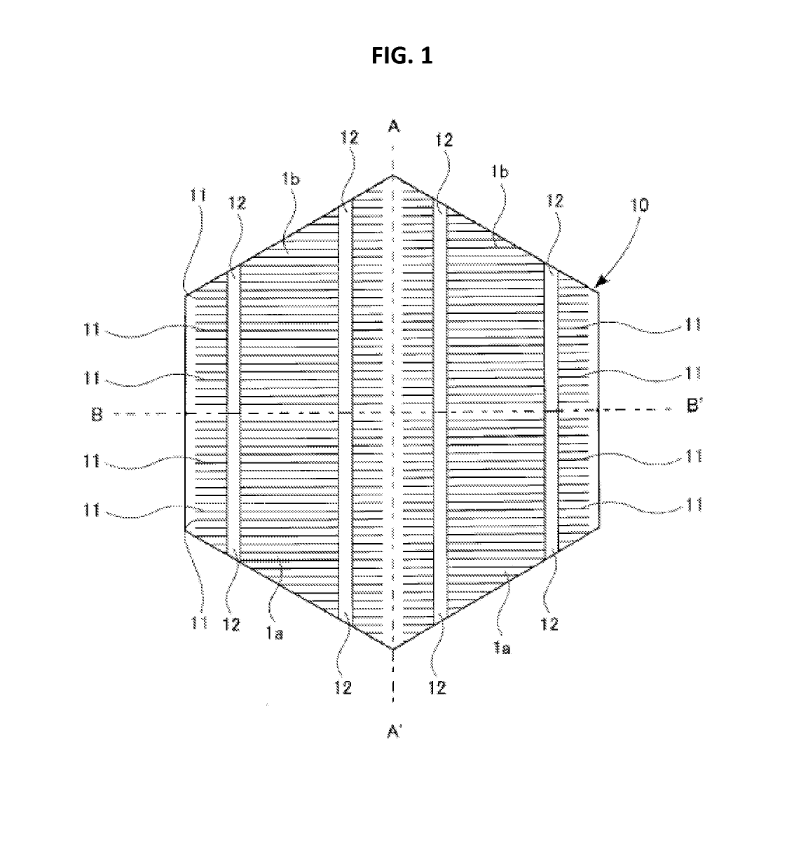

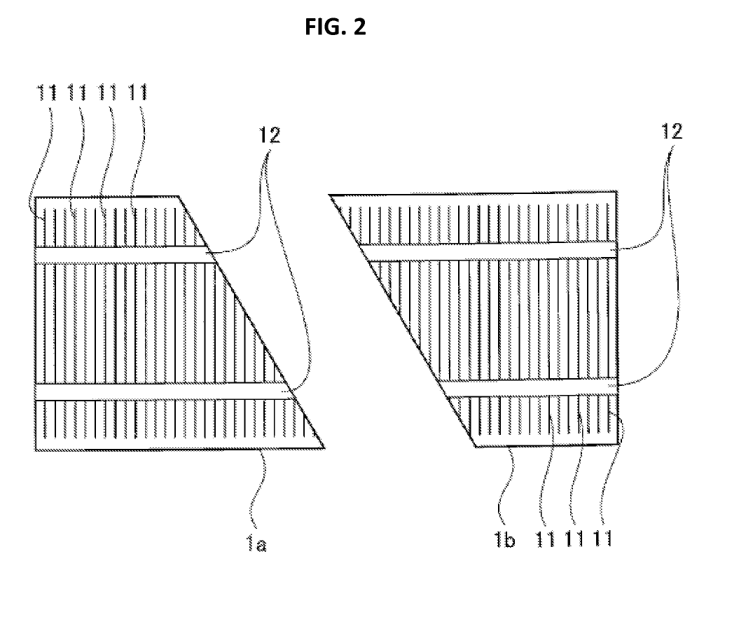

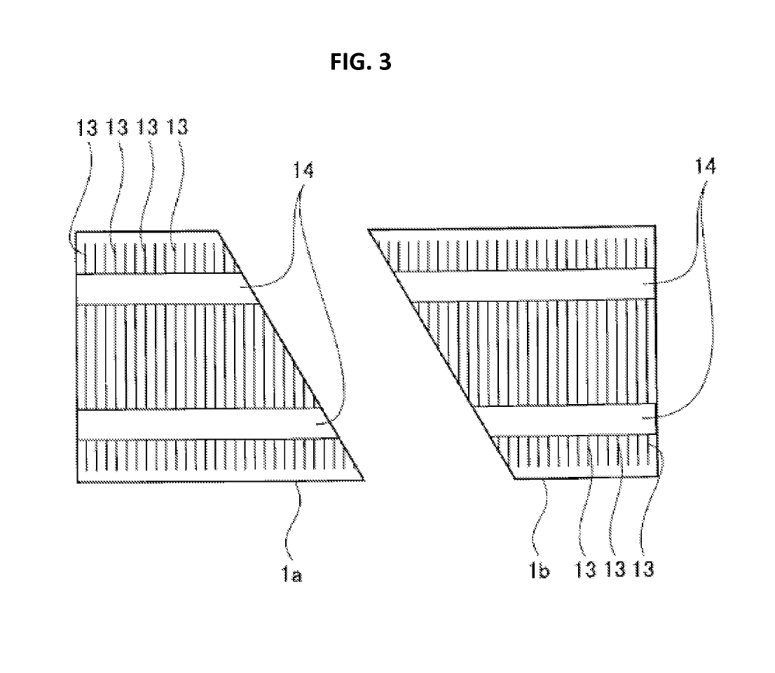

FIG. 1 shows the configuration of a solar cell substrate 10 which has not been divided into four solar cells yet, and FIGS. 2 and 3 show arranged two solar cells 1a and 1b, out of the divided four solar cells. As shown in the drawings, solar cell substrate 10 is shaped as a substantially-regular hexagon in a plan view. Finger electrodes 11 and bus bar electrodes 12 are formed on the front surface of solar cell substrate 10, and finger electrodes 13 and bus bar electrodes 14 are formed on the rear surface of solar cell substrate 10.

Solar cell substrate 10 is formed, for example, with an n-type region and a p-type region inside thereof such that a joint portion configured to generate an electric field for carrier separation is formed at an interface of the n-type region and the p-type region. The n-type region and the p-type region can be formed by one or a combination of semiconductors used for solar cells, the semiconductors including a crystal semiconductor such as single crystal silicon or polycrystalline silicon, a compound semiconductor such as GaAs or InP, thin-film silicon having an amorphous state or a microcrystalline state, or a thin-film semiconductor such as CuInSe. As an example, a solar cell having a what is called HIT (registered trademark) (Heterojunction with Intrinsic Thin-layer) structure is used. In the HIT structure, the property of the heterojunction interface is improved by interposing a thin intrinsic amorphous silicon layer between a single crystal silicon layer and an amorphous silicon layer which have conductivity types opposite to each other, so as to reduce a flaw at their interface.

Finger electrodes 11 and 13 mentioned above are electrodes configured to collect carriers from solar cell substrate 10. As shown in FIGS. 1 to 3, multiple finger electrodes 11 and 13 are formed in parallel to one another over the almost entire surface of solar cell substrate 10. For example, finger electrodes 11 and 13 are formed by, but not limited to, resin conductive paste having a resin material as a binder and conductive particles, such as silver particles, as a filler.

As shown in FIGS. 1 to 3, finger electrodes 11 and 13 are formed on the light receiving surfaces and the rear surfaces of solar cells 1a and 1b in the same manner. Finger electrodes 11 are formed on the light receiving surfaces of solar cells 1a and 1b, and finger electrodes 13 are formed on the rear surfaces of solar cells 1a and 1b.

Bus bar electrodes 12 and 14 are electrodes configured to collect the carriers from multiple finger electrodes 11 and 13, respectively. As shown in FIGS. 2 and 3, bus bar electrodes 12 and 14 intersect with finger electrodes 11 and 13. For example, bus bar electrodes 12 and 14 are formed by, but not limited to, resin conductive paste having a resin material as a binder and conductive particles, such as silver particles, as a filler, like finger electrodes 11 and 13.

As shown in FIG. 2, bus bar electrodes 12 are formed on the light receiving surfaces of solar cells 1a and 1b. As shown in FIG. 3, bus bar electrodes 14 are formed on the rear surfaces of solar cells 1a and 1b. The bus bar electrodes 14 formed on the rear surface have nothing to do with light receiving in this embodiment, and therefore may be formed wider than bus bar electrodes 12 on the light receiving surface.

The number of bus bar electrodes 12 and 14 can be appropriately set, in view of the sizes of solar cells 1a and 1b or the like. Solar cells 1a and 1b according to this embodiment each include two bus bar electrodes 12 and two bus bar electrodes 14, but may include three or more bus bar electrodes.

Solar cell substrate 10 shown in FIG. 1 is a substantially-regular hexagon in a plan view, but may be a pseudo-regular hexagon, instead. In addition, although FIG. 1 shows a solar cell in which the electrodes on the rear surface have a comb shape, a solar cell of a one-side light receiving type in which an electrode is uniformly formed on the rear surface of the solar cell may be used.

Solar cell substrate 10 shown in FIG. 1 is divided into four trapezoidal parts along a straight line (line A-A′ in FIG. 1) connecting two vertices and a straight line (line B-B′ in FIG. 1) connecting middle points of two opposite sides. Then, two of these divided parts are combined such that the upper surfaces of the two parts face one side while the lower surfaces of the two parts face the other side. Thus, solar cell unit 1 constituting of two solar cells 1a and 1b is formed.

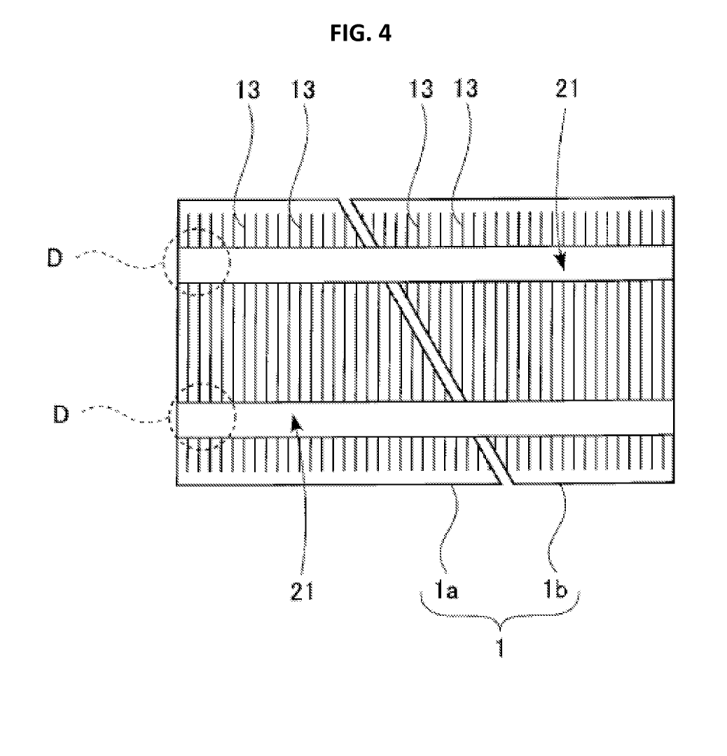

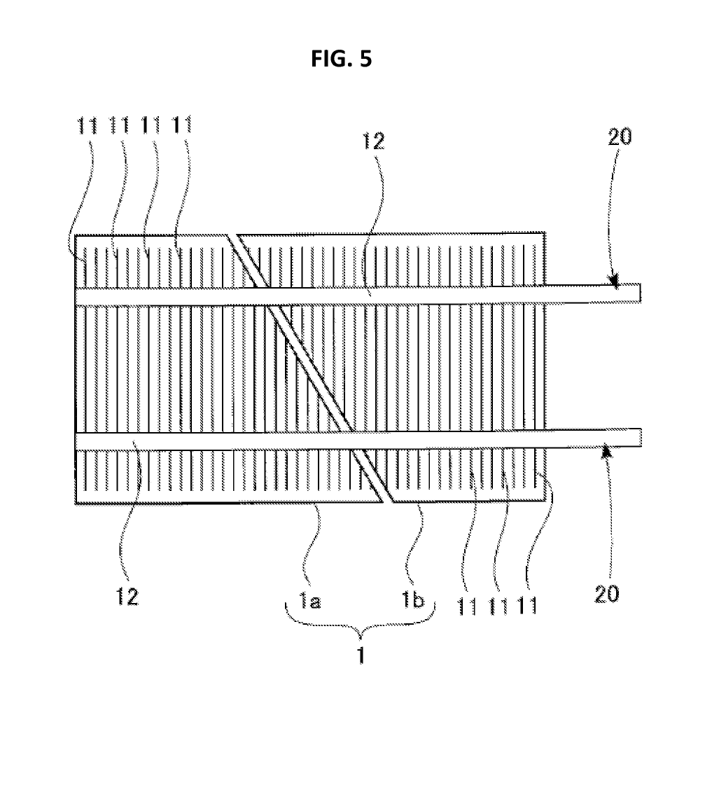

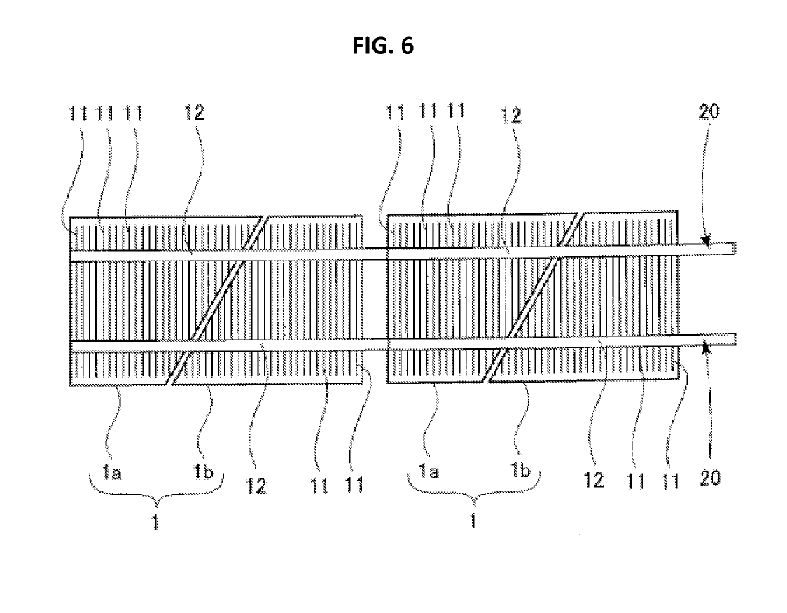

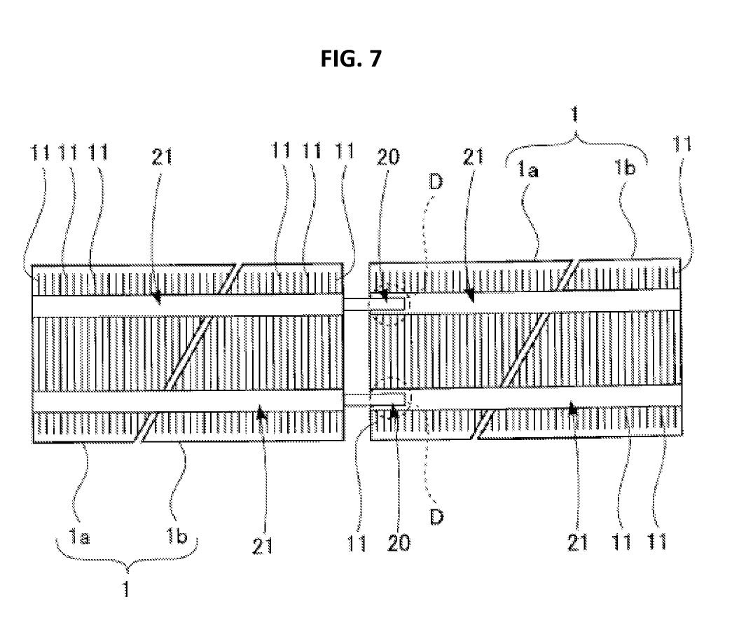

FIGS. 4, 5, 6, 7, 8A, 8B, and 9 show configuration examples of the solar cell unit and how the solar cell units are connected to each other. FIGS. 4 and 7 are plan views of the solar cell unit(s) seen from the rear side, and FIGS. 5 and 6 are plan views of the solar unit(s) seen from the front side. Note that each of the four parts divided from solar cell substrate 10 is simply called solar cell (1a or 1b) in the following.

To electrically connect solar cell 1a and solar cell 1b to each other, first, these solar cells 1a and 1b to be connected are placed such that the front surfaces of solar cell 1a and 1b face one direction while the rear surfaces of solar cells 1a and 1b face the other direction and oblique sides of solar cells 1a and 1b face each other without almost no displacement. Then, as shown in FIG. 4, two interconnection tabs 21 are placed on bus bar electrodes 14 on the rear surfaces of these two solar cells 1a and 1b. Two solar cells 1a and 1b are connected to each other in parallel by using these interconnection tabs 21, so as to form one solar cell unit 1.

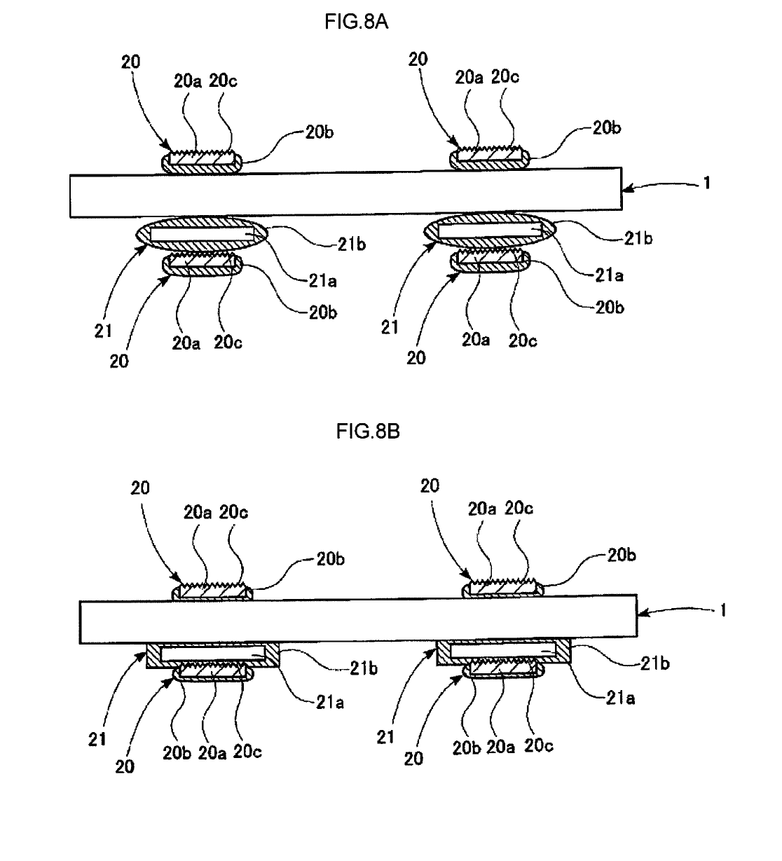

As shown in FIGS. 8A and 8B, each interconnection tab 21 includes copper foil 21a of about 150 μm thick and about 2 to 3 mm wide and lead-free solder 21b covering the surfaces of copper foil 21a formed by dipping copper foil 21 a into lead-free solder. The thickness of solder layer 21b on each of the front and rear surfaces of copper foil 21a is about 40 μm. Interconnection tabs 21 are placed on bus bar electrodes 14, and are heated to melt solder layers 21b. Thereby, interconnection tabs 21 are electrically and mechanically connected to bus bar electrodes 14 on the rear side of solar cell unit 1.

In this welding step of welding the interconnection tab 21, the area (indicated by D in the drawings) of interconnection tab 21 to be connected to interconnection tabs 20 drawn from the front side of adjacent solar cell unit 1 in the later step are unwelded, so that solder layer 21b at the area of interconnection tab 21 remain on interconnection tab 21. Solder layer 21 at other areas are melted to electrically and mechanically connect interconnection tabs 21 to bus bar electrodes 14 on the rear side. FIG. 8A shows a state where interconnection tabs 21 and interconnection tabs 20 are unwelded to each other.

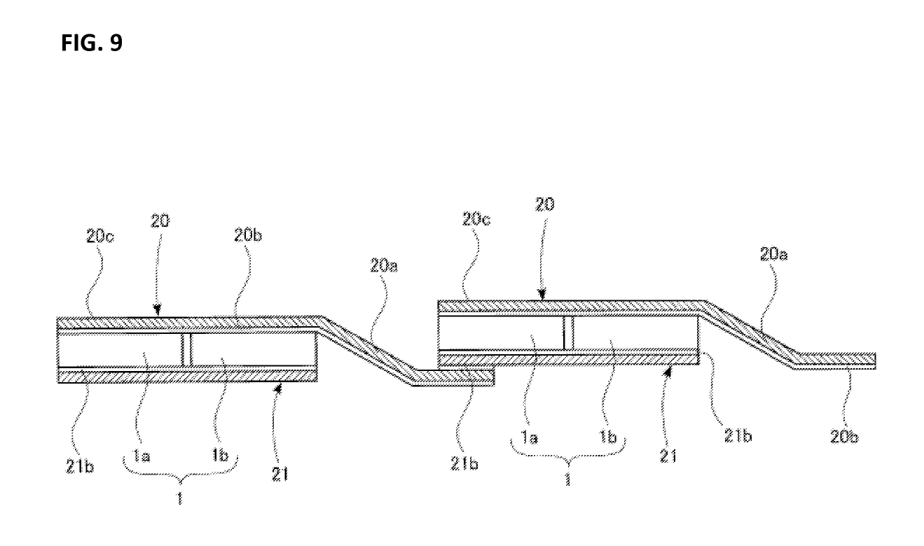

Then, as shown in FIG. 9, interconnection tabs 20 are drawn from the front surface of solar cell unit 1 comprising two solar cells 1a and 1b to the rear surface of adjacent solar cell unit 1 comprising two solar cells 1a and 1b, and are electrically connected to rear-side interconnection tabs 21 connecting two solar cells 1a and 1b of the adjacent solar cell unit 1.

Each of interconnection tabs 20 includes copper foil 20a of about 150 μm thick and about 2 mm wide and indentations on a front surface of copper foil 20a for light diffusion. A surface (a rear surface) of copper foil 20a having no indentation is dipped into lead-free solder so as to form solder layer 20b on the rear surface of copper foil 20a . The thickness of solder layer 20b on the rear surface of copper foil 20a is about 40 μm. Interconnection tabs 20 are placed on interconnection tabs 21, and are heated to melt solder layers 21b. Thereby, interconnection tabs 20 are electrically and mechanically connected to interconnection tabs 21 on the rear surface.

Before front-side interconnection tabs 20 are connected to part of rear-side interconnection tabs 21, solder layers 21b of rear-side interconnection tabs 21 are not welded yet at areas (indicated by D in the drawings) to be connected to front-side interconnection tabs 20. Accordingly, upon the welding step in which interconnection tabs 20 are connected to bus bar electrodes 12 at the front side and are connected to interconnection tabs 21 at the rear side, unwelded solder layers 21b of rear-side interconnection tabs 21 still exist between rear-side interconnection tabs 21 and front-side interconnection tabs 20. Therefore, interconnection tabs 20 and 21 can have a sufficient amount of solder between them to improve the connection strength of interconnection tabs 20 and 21 and to improve reliability.

As described above, solder in the areas (indicated by D in the drawings) of interconnection tabs 21 where interconnection tabs 20 and interconnection tabs 21 are to be connected to each other is unwelded in the previous step of welding interconnection tabs 21 to the rear side. As a result, as shown in FIGS. 8A and 8B, a sufficient amount of solder can be obtained even if interconnection tabs 20 whose front surfaces have indentations 20c to diffuse incident light are used. Interconnection tabs 20 whose front surfaces have indentations 20c to diffuse incident light are half-dipped interconnection tabs 20, that is, only the rear surfaces of interconnection tabs 20 are dipped to solder, so that the portion having indentations 20c has no or little solder. As shown in FIG. 8A, even when such half-dipped interconnection tabs 20 are used, unwelded solder layers 21b remains on rear-side interconnection tabs 21 upon welding of half-dipped interconnection tabs 20 to rear-side interconnection tab 21.

As shown in FIG. 8B, when front-side interconnection tabs 20 are welded to rear-side interconnection tabs 21 on the rear side, unwelded solder layers 21b on rear-side interconnection tabs 21 allows reliable electrical and mechanical connection between rear-side interconnection tabs 21 and front-side interconnection tabs 20. In this way, even when half-dipped interconnection tabs 20 are used, additional work such as additional soldering does not need to be performed.

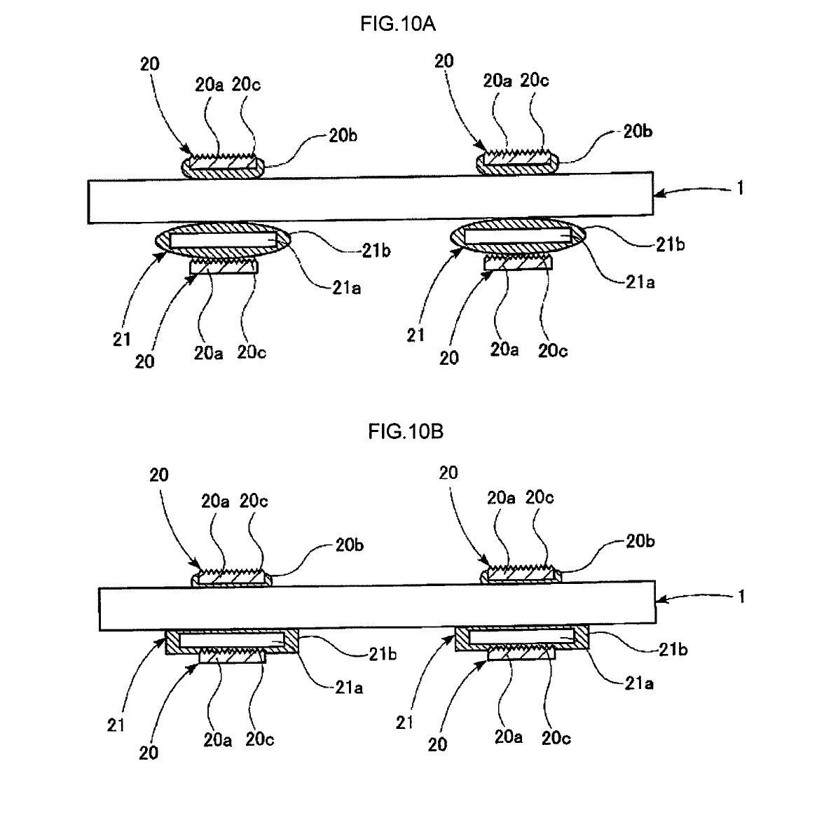

Since front-side interconnection tabs 20 are attached using unwelded solder layers 21b of rear-side interconnection tabs 21, interconnection tabs 20 do not have to have solder coat layers on their surfaces, as shown in FIGS. 10A and 10B illustrating a modification. FIG. 10A illustrates a relationship between front-side interconnection tabs 20 and rear-side interconnection tabs 21 before welding and FIG. 10B illustrates a connection state of front-side interconnection tabs 20 and rear-side interconnection tabs 20 after welding. In the modification shown in FIGS. 10A and 10B, each of interconnection tabs 20 provided with indentations 20c on their front surfaces to diffuse incident light does not have solder at least at an area to be attached to on rear-side interconnection tab 21. As shown in FIG. 10A, even through interconnection tabs 20 with no solder at least at the area to be attached to rear-side interconnection tab 21 is used, unwelded solder 21b on rear-side interconnection tabs 21 exists at the area where front-side interconnection tab 20 and rear-side interconnection tab 21 are to be connected with each other.

As shown in FIG. 10B, when front-side interconnection tabs 20 are welded to rear-side interconnection tabs 21 on the rear side, unwelded solder layers 21b on rear-side interconnection tabs 21 allows reliable electrical and mechanical connection between rear-side interconnection tabs 21 and front-side interconnection tabs 20. In this way, even when interconnection tabs 20 are not provided with solder at least at the areas to be attached to rear-side interconnection tabs 21, additional work such as additional soldering is not necessary.

Thus, solar cell units 1 are connected to each other in series with interconnection tabs 20. Thereafter, bus bar electrodes 12 on the front surfaces of two solar cells 1a and 1b of one solar cell unit 1 are electrically connected to interconnection tabs 21 on the rear surface of next solar cell unit 1 with two interconnection tabs 20, and then to the next unit, and so on to form a string of solar cells.

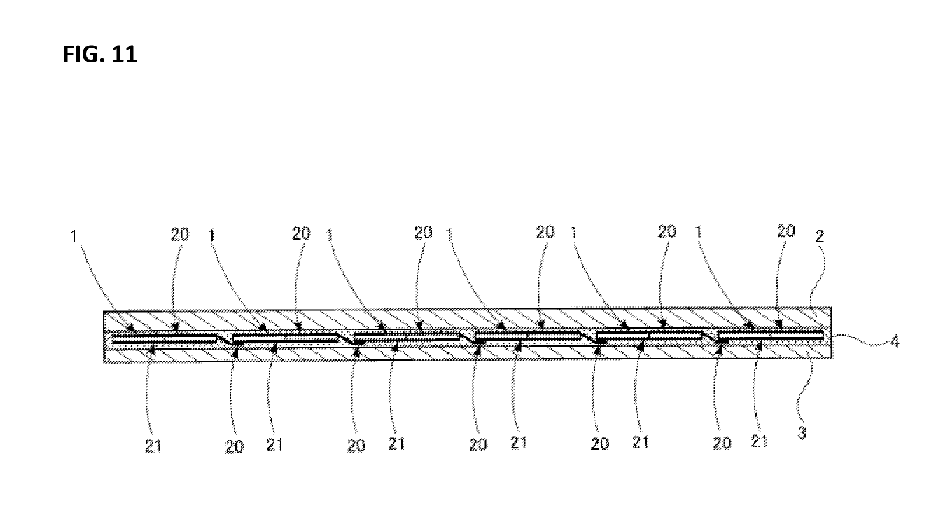

With reference to FIG. 11, the schematic configuration of a solar cell module according to the embodiment of the invention is described. FIG. 11 is a schematic sectional view of the solar cell module according to this embodiment.

The solar cell module has a solar cell string formed by connecting multiple solar cell units 1, front-side protection material 2, rear-side protection material 3, and a sealing material 4. The solar cell module is formed by sealing the solar cell string between front-side protection material 2 and rear-side protection material 3 with sealing material 4.

The solar cell string includes multiple solar cell units 1 and interconnection tabs 20 and 21. The solar cell string is formed by connecting solar cell units 1 with interconnection tabs 20, solar cell units 1 each being obtained by connecting solar cells 1a and 1b.

The interconnection tabs 20 are connected to electrodes formed on the light-receiving surfaces of solar cells 1a and 1b of one solar cell unit 1 and to interconnection tabs 21 connected to the rear surface of another solar cell unit 1 adjacent to the one solar cell unit 1. Thereby, adjacent solar cell units 1 are electrically connected to each other.

Front-side protection material 2 is arranged on the front surface of sealing material 4 and is configured to protect the front surface of the solar cell module. Translucent, water-shielding glass, translucent plastic, or the like can be used for front-side protection material 2.

Rear-side protection material 3 is arranged on the back surface of sealing material 4 and is configured to protect the rear surface of the solar cell module. As rear-side protection material 3, a resin film such as PET (Polyethylene Terephthalate), a laminated film in which an aluminum foil is sandwiched by resin films, or the like can be used.

Sealing material 4 is configured to seal solar cell string 1 between front-side protection material 2 and rear-side protection material 3. A translucent resin, such as an ethylene-vinyl acetate (EVA) copolymer, an ethylene-ethyl acrylate (EEA) copolymer, polyvinyl butyral (PVB), silicon, urethane, acryl, or epoxy, can be used for sealing material 4.

Note that an aluminum frame (not shown) may be attached to the outer periphery of the solar cell module having the above configuration.

In the above embodiment, two trapezoidal solar cells 1a and 1b are connected such that the front surfaces of solar cells 1a and 1b are oriented to one direction while the rear surfaces of solar cells 1a and 1b are oriented to the other direction and oblique sides of solar cells 1a and 1b face each other without almost no displacement. However, the shape of solar cells 1a and 1b is not limited to a trapezoid, and the invention can be applied to rectangular solar cells, as well.

Interconnection tabs 20 are provided with indentations on their surfaces herein, but do not have to be provided with indentations. Further, interconnection tabs 20 may have a linear shape.

It should be understood that the embodiment disclosed herein is given for illustrative purposes only, and not for restrictive purposes. The scope of the invention is shown not by the description of the embodiment above but by the scope of claims, and is intended to include all the modifications meaning equivalent to and within the scope of claims.

1. A method of manufacturing a solar cell module, the method comprising:,
a first welding step of connecting rear-side electrodes of solar cells with a rear-side interconnection tab to form a solar cell unit; and
a second welding step of connecting a front-side interconnection tab of another solar cell unit adjacent to the solar cell unit to the rear-side interconnection tab of the solar cell unit, at an unwelded part of solder of the rear interconnection tab of the solar cell unit.

2. The method of manufacturing the solar cell module according to claim 1, wherein
the first welding step connects the rear-side interconnection tab to the rear-side electrodes while remaining the unwelded part at the area to which the front-side interconnection tab is to be connected in the second welding step.

3. The method of manufacturing the solar cell module according to claim 1, wherein
the second welding step connects, in a state where an end portion of the front-side interconnection tab of the another solar cell unit is placed on the unwelded part of the rear-side interconnection tab of the solar cell unit, the front-side interconnection tab of the another solar cell unit to the rear-side interconnection tab of the solar cell unit, by melting the unwelded part.

4. The method of manufacturing the solar cell module according to claim 1, wherein
the front-side interconnection tab comprises a solder layer on one side and no solder layer on the other side thereof

5. The method of manufacturing the solar cell module according to claim 1, wherein
the front-side interconnection tab comprises no solder layer thereon.

6. The method of manufacturing the solar cell module according to claim 4, wherein
the front-side interconnection tab comprises indentations to diffuse light at least on a front surface thereof.

7. The method of manufacturing the solar cell module according to claim 5, wherein
the front-side interconnection tab comprises indentations to diffuse light at least on a front surface thereof.

8. A method of manufacturing a solar cell module, the method comprising:
connecting electrodes of solar cells with an interconnection tab so as to form a first solar cell unit, by welding the interconnection tab to the electrodes while remaining an unmelted part of solder of the interconnection tab, and
connecting an interconnection tab of a second solar cell unit to the interconnection tab of the first solar cell unit at the unmelted part of the interconnection tab of the first solar cell unit.
